(19) United States
(12) Patent Application Publication
(10) Pub. No.: US 2026/0143861 A1
(43) Pub. Date: May 21, 2026

(54) INGAN-BASED RED-LIGHT LED EPITAXIAL FILM STRUCTURE WITH FOLDED QUANTUM WELL LAYERS AND ITS APPLICATION

(71) Applicants: FOCUS LIGHTINGS TECH CO. LTD, SUZHOU, JIANGSU (CN); TIANJIN POLYTECHNIC UNIVERSITY, TIANJIN (CN)

(72) Inventors: HAN JIANG, SUZHOU, JIANGSU (CN); LIXIA ZHAO, SUZHOU, JIANGSU (CN); YANGYANG XU, SUZHOU, JIANGSU (CN); HU CHENG, SUZHOU, JIANGSU (CN); GUOCHANG LI, SUZHOU, JIANGSU (CN); SHUWEI YUAN, SUZHOU, JIANGSU (CN); WENJUN WANG, SUZHOU, JIANGSU (CN); ZHIJUN XU, SUZHOU, JIANGSU (CN)

(21) Appl. No.: 18/941,062

(22) Filed: Nov. 8, 2024

Related U.S. Application Data
(63) Continuation of application No. PCT/CN2024/111662, filed on Aug. 13, 2024.

(30) Foreign Application Priority Data
Jun. 24, 2024 (CN) 202410815317.4

(51) Int. Cl. H10H 20/812; H10H 20/825

(52) U.S. Cl. CPC H10H 20/812; H10H 20/825

(57) ABSTRACT

The invention provides an InGaN-based red-light LED epitaxial film structure with folded quantum well layers, addressing issues of material compatibility, process complexity, and light decay in current red-light LED technologies. By employing specially designed folded quantum wells, stress release layers, and porous structures, the epitaxial structure achieves red-light emission in the 600 nm-620 nm range and improves overall crystalline quality while effectively releasing internal stress. Additionally, optimized epitaxial layer structures and parameters enhance LED efficiency and stability. This innovation offers a promising solution for next-generation red-light LED development and holds significant application value in the semiconductor optoelectronics field.

### CROSS-REFERENCE TO RELATED APPLICATION

This application is a continuation of International Application No. PCT/CN 2024/111662, filed on Aug. 13, 2024, the disclosure of which is hereby incorporated by reference in its entirety.

### TECHNICAL FIELD

The present invention relates to the field of semiconductor optoelectronics, specifically to an Indium Gallium Nitride (InGaN)-based red-light Light Emitting Diode (LED) epitaxial film structure featuring folded quantum well layers.

### BACKGROUND

The core epitaxial material for red-light LED chips currently on the market is primarily Gallium Arsenide (GaAs), which plays a critical role in LED manufacturing. However, with the rapid development and widespread application of micro-LED technology across various fields, some issues have surfaced. Particularly, the compatibility between Gallium Arsenide materials and Gallium Nitride (GaN), which is widely used in blue and green LEDs, has become a key factor limiting further industry development.

This issue stems not only from the physical and chemical disparities between the two materials but also from their incompatibility in terms of process integration and performance. Additionally, the production of Gallium Arsenide materials involves a complex manufacturing process that requires multiple precise steps, which increases production costs and negatively impacts yield rates. Lower yield rates result in resource wastage and reduced profitability.

Additionally, Gallium Arsenide materials exhibit significant light decay, especially in small-sized LED chips, which remains a challenging issue. Despite multiple attempts by researchers and engineers to address this problem, no cost-effective solution has been found. This issue affects both LED product performance and lifespan, and to some extent, limits further advancements in LED technology.

In this context, the development of InGaN-based red-light LED epitaxial technology is constrained by the inherent physical properties of the material. This technology is viewed as a potential replacement for Gallium Arsenide, offering the possibility of becoming the core technology for the next generation of red-light LEDs. Its primary advantage lies in the potential to improve material and device uniformity, thus enhancing production efficiency. However, this technology also faces challenges.

InGaN-based red-light LED epitaxial technology is constrained by the material properties. Particularly, attempting to achieve high concentrations of Indium (In) doping often leads to degradation in crystal quality and band distortion, which affects carrier transport. These issues not only affect LED performance but also increase manufacturing difficulty and costs.

Thus, to advance InGaN-based red-light LED epitaxial technology, researchers are focused on improving the overall crystalline quality of GaN epitaxy and finding effective methods to release internal material stress. These efforts are crucial to improving LED product performance and reducing production costs, as well as driving the LED industry forward. Addressing these issues has become the primary task in the development of InGaN-based red-light LED epitaxial films.

### SUMMARY

The purpose of this invention is to provide an InGaN-based red-light LED epitaxial film structure with folded quantum well layers to address the aforementioned technical challenges. The invention utilizes specially designed folded quantum well layers to extend the emission wavelength of the LED epitaxial film to the red light range.

The technical solution of the present invention is as follows.

An InGaN-based red-light LED epitaxial film structure with folded quantum well layers, comprising:
a patterned sapphire substrate;
a composite buffer layer disposed on the patterned sapphire substrate;
an Undoped Gallium Nitride (Undoped-GaN) layer disposed on the composite buffer layer;
a stress release and porous structure generation layer disposed on the Undoped-GaN layer, comprising a multilayer structure of Undoped Indium Gallium Nitride (Undoped-InGaN) /H₂-etching/GaN, used to release stress and form a porous structure;
a GaN capping layer disposed on the stress release and porous structure generation layer;
an n-type GaN layer cycle structure disposed on the GaN capping layer, formed using low-temperature growth to create a rough surface;
a third stress release layer disposed on the n-type GaN layer cycle structure;
folded quantum well layers set on the third stress release layer, consisting of a cyclic structure of Indium Nitride (InN) layers, quantum wells, and quantum well barriers, wherein the number of cycles ranges between 5 and 20, the InN layer thickness is controlled between 0.5 nm and 1.0 nm, the quantum well is InGaN with a thickness ranging between 2 nm and 3 nm, wherein indium partially replaces gallium as a dopant, with a doping concentration of 30 mol % to 35 mol %;
quantum well barriers, including Barrier1, which is an Aluminum Gallium Nitride (AlGaN) layer with a thickness of 1 nm to 2 nm, wherein Aluminum (Al) partially replaces Gallium (Ga) in the form of doping, with a doping concentration of 20 mol % to 25 mol %, and Barrier2, which is GaN with a thickness of 2 nm to 3 nm;
a Low-Temperature p-type Gallium Nitride (LT-pGaN) layer, an Electron Blocking Layer (EBL), a High-Temperature p-type Gallium Nitride (HT-pGaN) layer, and a p-type contact layer sequentially disposed on the folded quantum well layers;
wherein the design of the folded quantum well layers enables the LED to emit red light with a peak wavelength controlled within the 600 nm-620 nm range. The composite buffer layer comprises a sequentially arranged Aluminum Nitride (AlN) material composite buffer layer and a low-temperature GaN material composite buffer layer.

During the growth of the stress release and porous structure generation layer, H₂-etching is used to remove surface and subsurface InN materials, forming a microporous structure.

The n-type GaN layer cycle structure includes Silicon-doped n-type GaN layers and Silicon-doped n-type InGaN layers, with the number of cycles ranging between 10-15. Each Silicon-doped n-type GaN layer has a thickness of 0.05 μm-0.1 μm, with a Silicon doping concentration ranging between 1.0E19-1.5E19 atoms/cm³. Each Silicon-doped n-type InGaN layer has a thickness of 0.1 μm-0.2 μm, with a Silicon doping concentration ranging between 1.0E19-1.5E19 atoms/cm³.

The emission peak wavelength of the InGaN-based red-light LED epitaxial film structure with folded quantum well layers is controlled within the red-light range of 600 nm-620 nm.

The preparation method for the InGaN-based red-light LED epitaxial film structure with folded quantum well layers includes specific growth steps, material selection, and parameter control. The growth steps include sequential growth of the composite buffer layer, Undoped-GaN layer, stress release and porous structure generation layer, GaN capping layer, n-type GaN layer cycle structure, third stress release layer, multi-quantum well light-emitting layers, LT-pGaN layer, EBL, HT-pGaN layer, and p-type contact layer. By adjusting precise parameters, the peak emission wavelength of the LED chip is controlled within the red-light range of 600 nm-620 nm.

In this invention, the design of the folded quantum well layers is the key innovation. Through specific growth steps and parameter control, red-light emission is achieved. The stress release and porous structure generation layer improves the overall crystalline quality of GaN epitaxy and releases stress. The n-type GaN layer cycle structure, grown at low temperatures, further releases stress and forms a rough surface. The multi-quantum well light-emitting layer includes a fine structure of quantum wells and quantum well barriers, as well as an InN layer used to increase the effective In doping concentration in the quantum wells. The design of the LT-pGaN layer, EBL, HT-pGaN layer, and p-type contact layer optimizes electron blocking and hole injection.

The beneficial effects of this invention are as follows: The design of the folded quantum well layers effectively improves the emission wavelength and efficiency of InGaN-based red-light LEDs. Additionally, the stress release and porous structure generation layer design effectively improves the overall crystalline quality of GaN epitaxy and releases stress. Furthermore, the structure exhibits good reproducibility and stability.

### BRIEF DESCRIPTION OF DRAWINGS

FIG. 1: Schematic diagram of the complete epitaxial structure of the invention.

FIG. 2: Schematic diagram of the Undoped-InGaN/H₂-etching/GaN multilayer structure.

FIG. 3: Transmission Electron Microscopy (TEM) characterization image of the Undoped-InGaN/H₂-etching/GaN multilayer structure with 20 loops.

FIG. 4A shows the emission wavelength of the LED structure without the Undoped-InGaN/H₂-etching/GaN multilayer porous layer.

FIG. 4B shows the emission wavelength of the LED structure with the Undoped-InGaN/H₂-etching/GaN multilayer porous layer.

FIG. 5: Schematic diagram of the n-type GaN layer cycle structure.

FIG. 6: Detailed structure and corresponding parameters of the multi-quantum well layer.

FIG. 7A: TEM characterization of the actual folded quantum well structure grown.

FIG. 7B: TEM structure image of the folded multi-quantum well from a wide-angle view.

FIG. 8: Photoluminescence (PL) spectrum with a peak wavelength of 616 nm and red-light emission during Electroluminescence (EL) testing.

### DETAILED DESCRIPTION OF EMBODIMENTS

Below is a detailed description of preferred embodiments of the present invention, provided in conjunction with the accompanying drawings to fully explain the technical solutions.

The present invention provides an InGaN-based red-light LED epitaxial film structure with folded quantum well layers (as shown in FIG. 1), which effectively addresses the existing challenges in red-light LED technology through a specially designed structure, achieving high-efficiency and high-quality red-light emission.

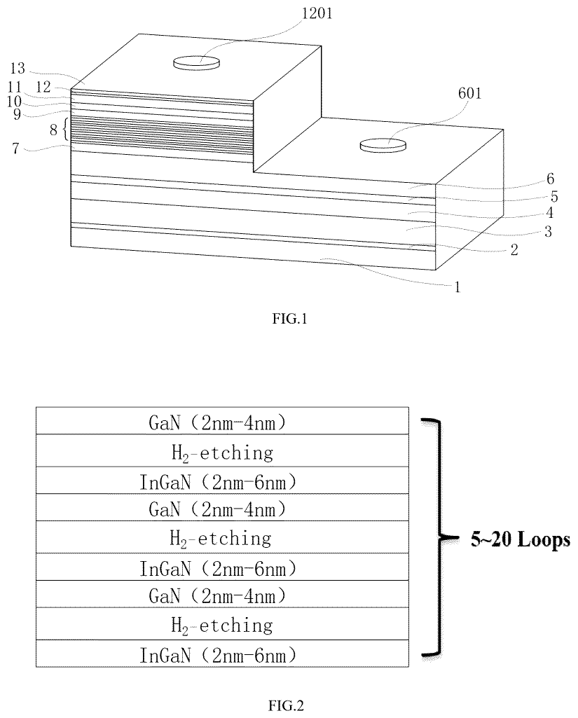

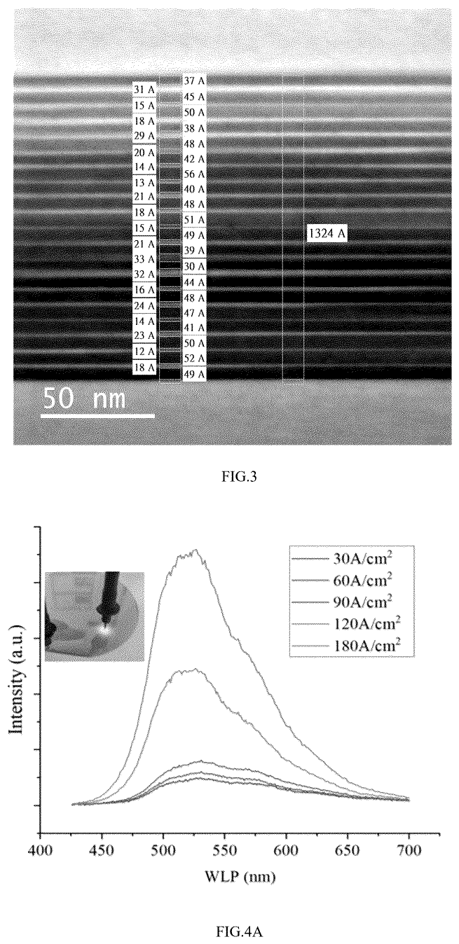

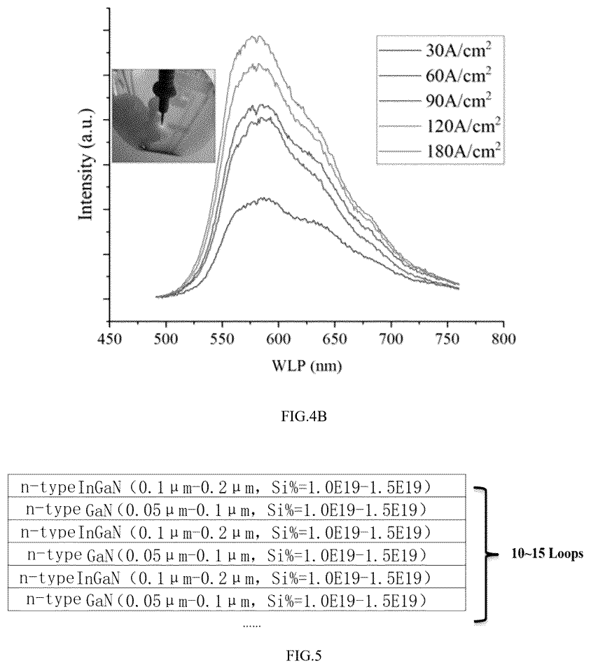

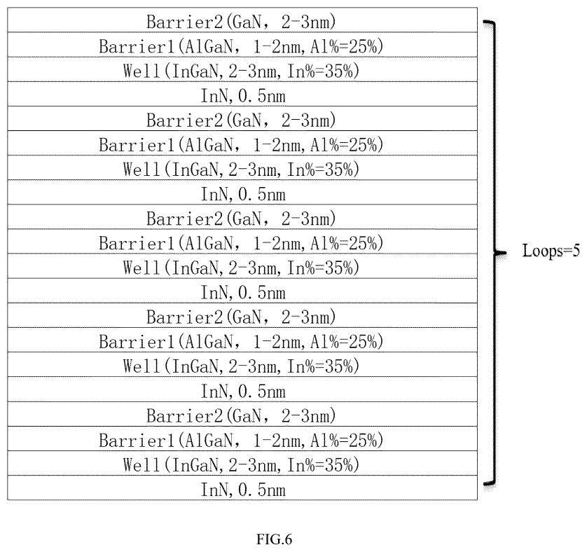

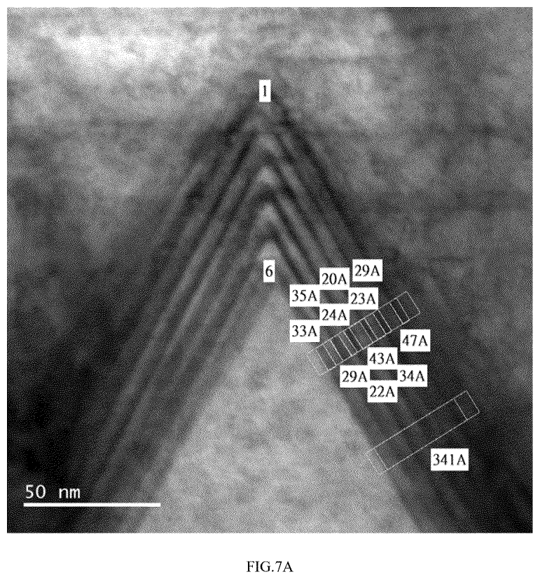

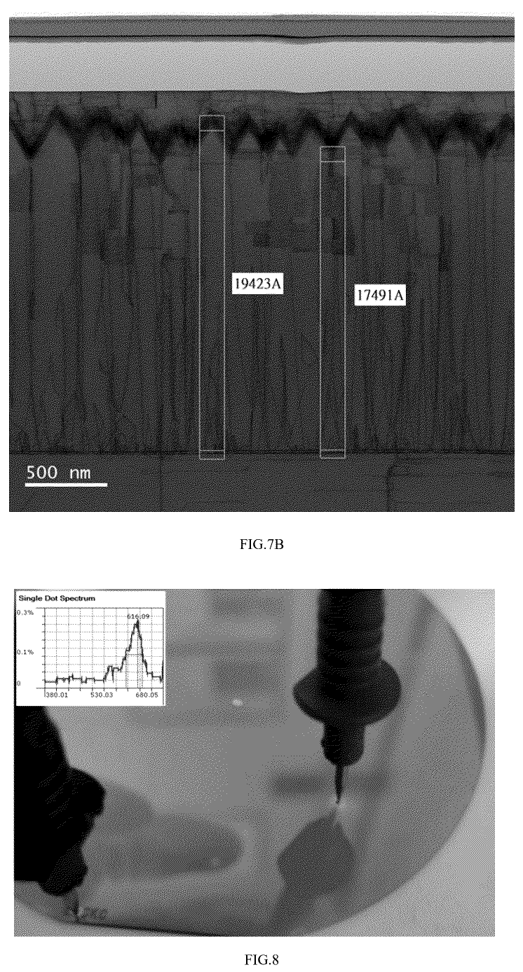

The specific steps are as follows:
Step 1: Substrate Preparation. First, select a patterned sapphire substrate 1 as the base. This substrate has good thermal stability and mechanical strength, making it suitable for LED epitaxy growth.
Step 2: Growth of the Composite Buffer Layer 2. First, use Physical Vapor Deposition (PVD) deposition technology to grow an AlN material composite buffer layer on the substrate, with a thickness ranging between 15 nm and 30 nm. This layer mainly alleviates lattice mismatch between the substrate and subsequent epitaxial layers. Next, use Metal Organic Chemical Vapor Deposition (MOCVD) technology to grow a low-temperature GaN material composite buffer layer on the AlN buffer layer, with a thickness between 10 nm and 30 nm, and a growth temperature maintained between 700° C.-850 ° C. This step helps to further improve the bonding quality between the epitaxial layer and the substrate.
Step 3: Growth of the Undoped-GaN Layer 3. On the composite buffer layer, grow an Undoped-GaN layer. This layer first flattens the patterned height of the substrate using a three-dimensional roughening layer, followed by the growth of a cover layer to smooth the surface of the GaN film, with an overall thickness ranging between 2.5 μm and 3.5 μm.
Step 4: Growth of the Stress Release and Porous Structure Generation Layer 4. On the flat Undoped-GaN layer, grow the first group of stress release and porous structure generation layers. The detailed structure is as follows: The Undoped-InGaN/H²-etching/GaN, with a thickness range of 2 nm-6 nm for InGaN. After the growth of InGaN, set a 150-300 second pause and switch the atmosphere to 50 vol. % N₂ and 50 vol. % H₂. Use H₂ to etch the surface and subsurface InN material, forming a microporous structure. After this, grow a GaN layer (2 nm-4 nm) to separate the InGaN layer and enlarge the porous cavity formed by H₂-etching, with a growth temperature set between 850° C.-950°C., and the growth temperature of the InGaN layer set between 720° C.-780°C. This step can be repeated 5 to 20 times to further enhance the stress relief effect. FIG. 2 shows the schematic diagram of the Undoped-InGaN/H₂-etching/GaN multilayer structure. This special structure, formed by H₂-etching, helps release the stress in the epitaxial layer. FIG. 3 shows the TEM characterization diagram of the 20-loop Undoped-InGaN/H₂-etching/GaN multilayer structure. The average thickness of the Undoped-InGaN layer is 4.5 nm, and the GaN layer has an average thickness of 2.2 nm. Compared to the initial design, the Undoped-InGaN layer's thickness has slightly decreased, while the GaN layer has thickened, mainly due to the H₂-etching of the InN in the Undoped-InGaN layer. However, the microporous morphology cannot be clearly observed at this level of TEM characterization accuracy. To demonstrate the effect of the Undoped-InGaN/H₂-etching/GaN multilayer porous structure on the emission wavelength of the LED structure, growth was carried out by removing the Undoped-InGaN/H₂-etching/GaN multilayer porous structure. In FIG. 4A, the peak wavelength is approximately 550 nm, and the emission color is yellow. In contrast, the peak wavelength of the structure with the Undoped-InGaN/H₂-etching/GaN multilayer porous structure is around 600 nm, with a red emission color, as shown in FIG. 4B.
Step 5: Growth of the GaN Capping Layer 5. After completing the growth of the stress release layer and porous layer cycle structure, grow an Undoped-GaN capping layer with a thickness of 0.2 μm-0.5 μm to isolate the doping from the above structure.
Step 6: Growth of the n-type GaN Layer Cycle Structure 6. On the smooth Undoped-GaN surface, grow an n-type GaN layer cycle structure. This structure is composed entirely of Silicon-doped n-type GaN layers, grown at low temperatures to reduce internal stress and create a rough surface for the subsequent folded quantum well layers. The cycle structure consists of Silicon-doped GaN/ Silicon-doped InGaN, with each cycle's thickness ranging between 0.15 μm-0.3 μm. The Indium doping concentration is ranging between 5.0E18-2.0E19 atoms/cm³, and the number of cycles is ranging between 10-15. The Silicon doping concentration ranges from 1.0E19 to 1.5E19 atoms/cm³. The overall thickness of the n-type GaN layer cycle structure is ranging between 1.5 μm-3.0 μm, with the growth temperature maintained between 850° C.-950 ° C. FIG. 5 shows the structure of the n-type GaN layer cycle structure.
Step 7: Growth of the Superlattice Structure 7. On top of the n-type GaN cycle structure, grow a superlattice structure composed of low Silicon-doped (1.0E19-2.0E19 atoms/cm³) n-type GaN as the barrier and low Indium-doped (5.0E18-2.0E19 atoms/cm³) and Silicon-doped (1.0E19-2.0E19 atoms/cm³) n-type InGaN as the well. This superlattice structure acts as the third stress release layer, with an overall thickness range of 0.5μm-1.0 μm.
Step 8: Growth of the Folded Quantum Well Layers 8. The detailed structure and parameters of the folded quantum well layers are shown in FIG. 6. The folded quantum well structure is designed to increase the effective Indium doping concentration in the Well. The folded quantum well layers consist of InN layers, quantum wells, and quantum well barriers in a cyclic structure. In this example, the number of cycles is controlled at 5, with the InN layer thickness controlled at 0.5 nm, the quantum well thickness at 2 nm-3 nm of InGaN, and an Indium doping concentration of 35 at. %. The quantum well barriers include Barrier1 and Barrier2, where Barrier1 is an AlGaN layer with a thickness ranging between 1 nm-2 nm and an Al doping concentration of 25 at. %, and Barrier2 is a GaN layer with a thickness ranging between 2 nm-3 nm. The InN layer can increase the effective Indium doping concentration in the quantum well. FIG. 7A shows the actual TEM characterization of the grown folded quantum well structure. In FIG. 7A, the average well thickness is 2.36 nm=(23+20+24+22+29) Å/5, and the average barrier thickness is 3.84 nm=(47+34+43+35+33) Å/5. There is a deviation from the design values, which can be attributed to both characterization fluctuations and the actual thickness difference between the folded quantum well grown on a flat C-plane and the designed value. FIG. 7B shows the folded multi-quantum well TEM structure under a wide-angle view.

Subsequent Layer Growth: After the growth of the multi-quantum well layer is complete, grow the LT-pGaN layer 9, EBL 10, HT-pGaN layer 11, and p-type contact layer 12 sequentially. These layers improve the light emission efficiency and stability of the LED. The LT-pGaN layer has a thickness ranging from 15 nm to 30 nm, with Mg doping concentrations of 5.0E19 to 1.0E21 atoms/cm³, In doping concentrations of 1.0E18 to 1.0E19 atoms/cm³, and Al doping concentrations of 1.0E18 to 5.0E18 atoms/cm³. The EBL's thickness is 20 nm-40 nm, with an Al doping concentration that gradually decreases from 1.0E21 atoms/cm³ to 1.0E19 atoms/cm³. The HT-pGaN layer's thickness is 15 nm-30 nm, with a Magnesium (Mg) doping concentration of 1.0E20-1.0E21 atoms/cm³. The p-type contact layer's thickness is 5 nm-10 nm, with an Mg doping concentration of 1.0E21-2.0E21 atoms/cm³. Inductively Coupled Plasma-etching (ICP-etching) is used to form the electrode interface of the n-type GaN layer cycle structure, and Indium Tin Oxide (ITO) transparent conductive film 13 is deposited on the p-type contact layer with a thickness ranging between 30 nm-110 nm.

Electrode Fabrication and Testing. Finally, fabricate the LED chip electrodes, including the positive electrode p-type PAD 1201 and the negative electrode n-type PAD 601, and other process layers, and then perform point testing. By adjusting precise parameters, the peak emission wavelength of the InGaN-based red-light LED can be controlled within the red-light range of 600 nm-620 nm, demonstrating excellent optoelectronic performance. FIG. 8 presents the PL spectrum exhibiting a peak wavelength of 616 nm and red-light emission observed during EL testing.

In summary, through the special design of the folded quantum well layers and the optimization of other epitaxial layers, the present invention successfully achieves high-efficiency and high-quality red-light emission. This technical solution provides new approaches and methods for the development of red-light LED, with important application value and development prospects.

What is claimed is:

1. An Indium Gallium Nitride-based red-light Light Emitting Diode epitaxial film structure with folded quantum well layers, comprising:
a patterned sapphire substrate;
a composite buffer layer disposed on the patterned sapphire substrate;
an Undoped Gallium Nitride layer disposed on the composite buffer layer;
a stress release and porous structure generation layer disposed on the Undoped Gallium Nitride layer, comprising a multilayer structure of Undoped Indium Gallium Nitride/H₂-etching/Gallium Nitride, used to release stress and form a porous structure;
a Gallium Nitride capping layer disposed on the stress release and porous structure generation layer;
an n-type Gallium Nitride layer cycle structure disposed on the Gallium Nitride capping layer, formed using low-temperature growth to create a rough surface;
a third stress release layer disposed on the n-type Gallium Nitride layer cycle structure;
folded quantum well layers set on the third stress release layer, consisting of a cyclic structure of Indium Nitride layers, quantum wells, and quantum well barriers, wherein the number of cycles ranges between 5 and 20, the Indium Nitride layer thickness is controlled between 0.5 nm and 1.0 nm, the quantum well is Indium Gallium Nitride with a thickness ranging between 2 nm and 3 nm, wherein indium partially replaces gallium as a dopant, with a doping concentration of 30 mol % to 35 mol %;
quantum well barriers, including Barrier1, which is an Aluminum Gallium Nitride layer with a thickness of 1 nm to 2 nm, wherein Aluminum partially replaces Gallium in the form of doping, with a doping concentration of 20 mol % to 25 mol %, and Barrier2, which is a Gallium Nitride layer with a thickness of 2 nm to 3 nm;
a Low-Temperature p-type Gallium Nitride layer, an Electron Blocking Layer, a High-Temperature p-type Gallium Nitride layer, and a p-type contact layer sequentially disposed on the folded quantum well layers;
wherein the design of the folded quantum well layers enables the Light Emitting Diode to emit red light with a peak wavelength controlled within the 600 nm-620 nm range.

2. The Indium Gallium Nitride-based red-light Light Emitting Diode epitaxial film structure with folded quantum well layers according to claim 1, wherein the composite buffer layer comprises a sequentially arranged Aluminum Nitride material composite buffer layer and a low-temperature Gallium Nitride material composite buffer layer.

3. The Indium Gallium Nitride-based red-light Light Emitting Diode epitaxial film structure with folded quantum well layers according to claim 1, wherein the stress release and porous structure generation layer comprises 5-20 layers of Undoped Indium Gallium Nitride/H₂-etching/Gallium Nitride structures.

4. The Indium Gallium Nitride-based red-light Light Emitting Diode epitaxial film structure with folded quantum well layers according to claim 1, wherein the n-type GaN layer cycle structure comprises Silicon-doped n-type Gallium Nitride layers and Silicon-doped n-type Indium Gallium Nitride layers, with the number of cycles ranging between 10-15.

5. The Indium Gallium Nitride-based red-light Light Emitting Diode epitaxial film structure with folded quantum well layers according to claim 4, wherein each Silicon-doped n-type Gallium Nitride layer has a thickness ranging between 0.05 μm-0.1 μm, with a Silicon doping concentration ranging between 1.0E19-1.5E19 atoms/cm³.

6. The Indium Gallium Nitride-based red-light Light Emitting Diode epitaxial film structure with folded quantum well layers according to claim 4, wherein each Silicon-doped n-type Indium Gallium Nitride layer has a thickness ranging between 0.1 μm-0.2 μm, with a Silicon doping concentration ranging between 1.0E19-1.5E19 atoms/cm³.

7. The Indium Gallium Nitride-based red-light Light Emitting Diode epitaxial film structure with folded quantum well layers according to claim 1, wherein the emission peak wavelength is controlled within the red-light range of 600 nm-620 nm.

8. Use of the Indium Gallium Nitride-based red-light Light Emitting Diode epitaxial film structure with folded quantum well layers according to claim 1 in the field of semiconductor optoelectronics.
